(19) United States
(12) Patent Application Publication
(10) Pub. No.: US 2011/0284074 A1
(43) Pub. Date: Nov. 24, 2011

(54) PHOTOVOLTAIC CELL

(75) Inventors: Chee-Wee Liu, Taipei City (TW); Wei-Shuo Ho, Taipei County (TW); Yen-Yu Chen, Kaohsiung City (TW); Chun-Yuan Ku, Taipei City (TW); Chien-Jen Chen, Hsinchu City (TW); Han-Tu Lin, Hsinchu County (TW); Shuo-Wei Liang, Hsinchu County (TW)

(73) Assignee: AU OPTRONICS CORPORATION, Hsinchu (TW)

(21) Appl. No.: 12/891,721

(22) Filed: Sep. 27, 2010

(30) Foreign Application Priority Data
May 18, 2010 (TW) 99115781

(51) Int. Cl. H01L 31/0376

(52) U.S. Cl. 136/258

(57) ABSTRACT

A photovoltaic cell includes a first type doped mono-crystalline silicon substrate, an intrinsic amorphous silicon layer, a second type doped amorphous silicon layer, a first type doped crystalline Ge-containing layer, and a pair of electrodes. The first type doped mono-crystalline silicon substrate has a front surface and a rear surface. The intrinsic amorphous silicon layer is disposed on the front surface. The second type doped amorphous silicon layer is disposed on the intrinsic amorphous silicon layer. The first type doped crystalline Ge-containing layer is disposed on the rear surface. The pair of electrodes are electrically connected to the second type doped amorphous silicon layer and first type doped crystalline Ge-containing layer, respectively.

### CROSS-REFERENCE TO RELATED APPLICATION

This application claims the priority benefit of Taiwan application serial no. 99115781, filed on May 18, 2010. The entirety of the above-mentioned patent application is hereby incorporated by reference herein and made a part of this specification.

### BACKGROUND OF THE INVENTION

1. Field of the Invention

The present invention relates to a photovoltaic cell, and more particularly, to a photovoltaic cell with highly photoelectric conversion efficiency.

2. Description of Related Art

As a clean, inexhaustible energy, the solar energy has been the focus in addressing the current pollution and shortage issues of petrochemical energy. Because of the capability of directly converting the solar energy into electric power, photovoltaic cells has become an import subject to research.

Silicon-based photovoltaic cells are a typical photovoltaic cell in the industry. The principle of the silicon-based photovoltaic cell is that two semiconductor layers of different types (p type and n type) are joined to form a p-n junction; when the sunlight illuminates the semiconductor layers having such a p-n junction, the energy of photons of light can excite electrons from a semiconductor valence band to a conduction band to generate electron-hole pairs; both electrons and holes are influenced by an electric field such that the holes move along the direction of the electric field while the electrons move in an opposite direction. If the photovoltaic cell and a load are connected via a wire, this can form a loop allowing a current to flow through the load.

In hetero junction with intrinsic thin layer (HIT) photovoltaic cells, two semiconductor layers of different types (p type and n type) are doped mono-crystalline silicon layer and doped amorphous silicon layer, respectively. In addition, an intrinsic amorphous silicon layer is disposed between the doped mono-crystalline silicon layer and the doped amorphous silicon layer. Furthermore, a pair of electrodes are directly contacted to the doped mono-crystalline silicon layer and the doped amorphous silicon layer, respectively. However, conventional HIT photovoltaic cell structures can only absorb photons of the solar spectrum that have energy substantially greater than the silicon band gap (1.12 eV). Therefore, the conventional photovoltaic cells can hardly have good photoelectric conversion efficiency.

### SUMMARY OF THE INVENTION

Accordingly, the present invention is directed to a photovoltaic cell which has improved photoelectric conversion efficiency.

The present invention provides a photovoltaic cell including a first type doped mono-crystalline silicon substrate, an intrinsic amorphous silicon layer, a second type doped amorphous silicon layer, a first type doped crystalline Ge-containing layer, and a pair of electrodes. The first type doped mono-crystalline silicon substrate has a front surface and a rear surface. The intrinsic amorphous silicon layer is disposed on the front surface. The second type doped amorphous silicon layer is disposed on the intrinsic amorphous silicon layer. The first type doped crystalline Ge-containing layer is disposed on the rear surface. The pair of electrodes are electrically connected to the second type doped amorphous silicon layer and the first type doped crystalline Ge-containing layer, respectively.

According to one embodiment of the present invention, the first type doped mono-crystalline substrate has a crystalline orientation of (100), (110), or (111).

According to one embodiment of the present invention, the first type doped mono-crystalline silicon substrate is a p type doped mono-crystalline silicon substrate, and the second type doped amorphous silicon layer is an n type doped amorphous silicon layer.

According to one embodiment of the present invention, the band gap of the second type doped amorphous silicon layer is, for example, substantially less than the band gap of the intrinsic amorphous silicon layer, the band gap of the intrinsic amorphous silicon layer is, for example, substantially greater than the band gap of the first type doped mono-crystalline silicon substrate, and the band gap of the first type doped mono-crystalline silicon substrate is, for example, substantially greater than the first type doped crystalline Ge-containing layer.

According to one embodiment of the present invention, the band gap of the second type doped amorphous silicon layer ranges, for example, between about 1.5 eV and about 2.0 eV, the band gap of the intrinsic amorphous silicon layer ranges, for example, between about 1.5 eV and about 2.0 eV, the band gap of the first type doped mono-crystalline silicon substrate ranges, for example, between about 1.0 eV and about 1.1 eV, and the band gap of the first type doped crystalline Ge-containing layer ranges, for example, between about 0.6 eV and about 1.1 eV.

According to one embodiment of the present invention, the thickness of the first type doped mono-crystalline silicon substrate ranges, for example, between about 50 um and about 500 um.

According to one embodiment of the present invention, the doping concentration of the first type doped mono-crystalline silicon substrate ranges, for example, between about 10¹⁵ cm⁻³ and about 10¹⁷ cm⁻³.

According to one embodiment of the present invention, the thickness of the second type amorphous silicon layer ranges, for example, between about 1 nm and about 20 nm.

According to one embodiment of the present invention, the doping concentration of the second type doped amorphous silicon layer ranges, for example, between about 10¹⁸ cm⁻³ and about 10²¹ cm⁻³.

According to one embodiment of the present invention, the first type doped crystalline Ge-containing layer is, for example, a first type doped crystalline SiGe layer or a first type doped crystalline GeSn layer.

According to one embodiment of the present invention, the Ge content in the first type doped crystalline Ge-containing layer is, for example, substantially higher than 10%, and the Si content in the first type doped crystalline Ge-containing layer is, for example, substantially lower than 90%.

According to one embodiment of the present invention, the thickness of the first type doped crystalline Ge-containing layer ranges, for example, between about 10 nm and about 10 um.

According to one embodiment of the present invention, the doping concentration of the first type doped crystalline Ge-containing layer ranges, for example, between about 10¹⁵ cm⁻³ and about 10²¹ cm⁻³.

According to one embodiment of the present invention, the pair of electrodes may include a first electrode and a second electrode. The first electrode is disposed on the second type doped amorphous silicon layer. The second electrode is disposed on the first type doped crystalline Ge-containing layer. The second electrode and the first type doped mono-crystalline silicon substrate are disposed on opposite sides of the first type doped crystalline Ge-containing layer, respectively.

According to one embodiment of the present invention, the first electrode is a transparent electrode, and the second electrode is a reflective electrode.

In view of the foregoing, in the present invention, the first type doped crystalline Ge-containing layer is disposed between the first type doped mono-crystalline silicon substrate and the reflective electrode. The first type doped crystalline Ge-containing layer has the smallest band gap in the photovoltaic cell of the present invention. Therefore, the first type doped crystalline Ge-containing layer can absorb those solar spectrum that cannot be absorbed by the second type doped amorphous silicon layer, the intrinsic amorphous silicon layer, and the first type doped mono-crystalline silicon substrate to generate more electron-hole pairs, such that the photovoltaic cell can have a high photoelectric conversion efficiency.

Other objectives, features and advantages of the present invention will be further understood from the further technological features disclosed by the embodiments of the present invention wherein there are shown and described preferred embodiments of this invention, simply by way of illustration of modes best suited to carry out the invention.

### BRIEF DESCRIPTION OF THE DRAWINGS

FIG. 1 is a cross-sectional view of a photovoltaic cell according to one embodiment of the present invention.

FIG. 2 illustrates a relationship between the Ge content in the first type doped crystalline SiGe layer and conduction band energy/valence band energy of the first type doped crystalline SiGe layer.

FIG. 3 illustrates a relationship between the Ge content in the first type doped crystalline SiGe layer and the band gap of the first type doped crystalline SiGe layer.

FIG. 4 illustrates a relationship between the thickness of the first type doped crystalline SiGe layer and the photoelectric conversion efficiency/open-circuit voltage/short-circuit current/fill factor of the photovoltaic cell.

### DESCRIPTION OF THE EMBODIMENTS

FIG. 1 is a cross-sectional view of a photovoltaic cell according to one embodiment of the present invention. Referring to FIG. 1, the photovoltaic cell 10 includes a first type doped mono-crystalline silicon substrate 100, an intrinsic amorphous silicon layer 102, a second type doped amorphous silicon layer 104, a first type doped crystalline Ge-containing layer 106, and a pair of electrodes 108, 110.

The first type doped mono-crystalline silicon substrate 100 is, for example, a p-type doped mono-crystalline silicon substrate with a crystal orientation of, for example, (100), (110), or (111). The first type doped mono-crystalline silicon substrate 100 has a front surface 100a and a rear surface 100b. In the present embodiment, the front surface 100a and the rear surface 100b are, for example, configured as rough surfaces to reduce reflection of sunlight or light entering the photovoltaic cell 10. The thickness of the first type doped mono-crystalline silicon substrate 100 ranges, for example, between about 50 um and about 500 um, and the doping concentration of the first type doped mono-crystalline silicon substrate 100 ranges, for example, between about 10¹⁵ cm⁻³ and about 10¹⁷ cm⁻³.

In the present embodiment, the intrinsic amorphous silicon layer 102 is disposed on the front surface (or namely front side) 100a. For example, the thickness of the intrinsic amorphous silicon layer 102 ranges, for example, between about 1 nm and about 20 nm.

The second type doped amorphous silicon layer 104 is disposed on the intrinsic amorphous silicon layer 102. The second type doped amorphous layer 104 is, for example, an n-type doped amorphous silicon layer. The thickness of the second type doped amorphous silicon layer 104 ranges, for example, between about 1 nm and about 20 nm, and the doping concentration of the second type doped amorphous silicon layer 104 ranges, for example, between about 10¹⁸ cm⁻³ and about 10²¹ cm⁻³.

The first type doped crystalline Ge-containing layer 106 is disposed on the rear surface (or namely backside) 100b. The first type doped crystalline Ge-containing layer 106 is, for example, a first type doped crystalline SiGe layer, a first type doped crystalline GeSn layer or of another suitable material. In the embodiment of the present invention, the first type doped crystalline Ge-containing layer 106 is exemplarily implemented as a first type doped crystalline SiGe layer, but this should not be regarded as limiting. The thickness of the first type doped crystalline Ge-containing layer 106 ranges, for example, between about 10 nm and about 10 um, and the doping concentration of the first type doped crystalline Ge-containing layer 106 ranges, for example, between about 10¹⁵ cm⁻³ and about 10²¹ cm⁻³. The first type doped crystalline Ge-containing layer 106 can balance the stress generated by the intrinsic amorphous silicon layer 102 and the second type doped amorphous silicon layer 104 as well as provide a rear surface field (BSF) or rear surface electric field. Besides, the first type doped crystalline Ge-containing layer 106 is a crystalline structure which has less defects and therefore can reduce the likelihood of recombination of electrons and holes.

The electrode 108 is electrically connected with the second type doped amorphous silicon layer 104 and the electrode 110 is electrically connected with the first type doped crystalline Ge-containing layer 106. The electrode 110 and the first type doped mono-crystalline silicon substrate 100 are disposed on opposite sides of the first type doped crystalline Ge-containing layer 106. The electrode 108 is, for example, a transparent electrode which may be of indium tin oxide (ITO), indium zinc oxide (IZO), zinc oxide (ZnO), another suitable material, or any combination thereof. In addition, in another embodiment, an anti-reflective layer (not shown) may be coated on the surface of the electrode 108 to further reduce the reflection of the sunlight when entering the photovoltaic cell 10. Besides, the electrode 110 is, for example, a reflective electrode, the material of which may be metal (e.g. Al, Ag, Pt), alloy, or other suitable materials. For example, the thickness, area, and shape of the electrode 110 may be adjusted depending upon actual requirements.

In addition, the band gap of the second type doped amorphous silicon layer 104 is, for example, substantially less than the band gap of the intrinsic amorphous silicon layer 102, the band gap of the intrinsic amorphous silicon layer 102 is, for example, substantially greater than the band gap of the first type doped mono-crystalline silicon substrate 100, and the band gap of the first type doped mono-crystalline silicon substrate 100 is, for example, substantially greater than the first type doped crystalline Ge-containing layer 106. The band gap of the second type doped amorphous silicon layer 104 ranges, for example, between about 1.5 eV and about 2.0 eV, the band gap of the intrinsic amorphous silicon layer 102 ranges, for example, between about 1.5 eV and about 2.0 eV, the band gap of the first type doped mono-crystalline silicon substrate 100 ranges, for example, between about 1.0 eV and about 1.1 eV, and the band gap of the first type doped crystalline Ge-containing layer 106 ranges, for example, between about 0.6 eV and about 1.1 eV. That is, the first type doped crystalline Ge-containing layer 106 has the smallest band gap in the photovoltaic cell 10. Therefore, the first type doped crystalline Ge-containing layer 106 can absorb those solar spectrum that cannot be absorbed by the second type doped amorphous silicon layer 104, the intrinsic amorphous silicon layer 102 and the first type doped mono-crystalline silicon substrate 100 to generate more electron-hole pairs, thereby increasing the short-circuit current and resulting in a higher photoelectric conversion efficiency of the photovoltaic cell.

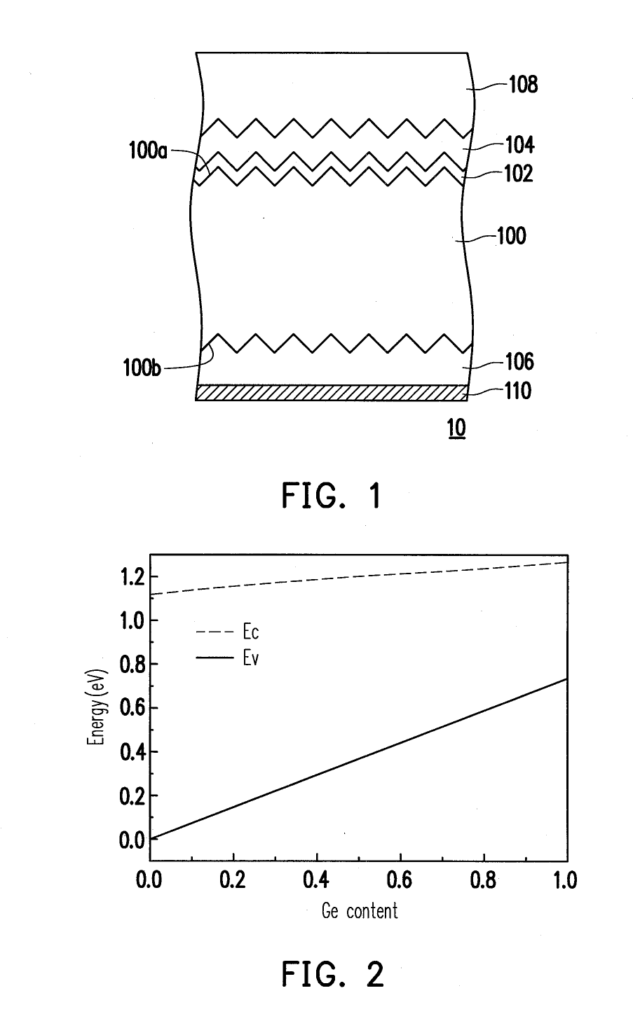

In the first type doped crystalline Ge-containing layer 106 (taking the first type doped crystalline SiGe layer as an example), the Ge content is, for example, substantially higher than 10%, and the Si content is, for example, substantially lower than 90%. In other words, if the first type doped crystalline Ge-containing layer uses the material of the first type doped crystalline SiGe layer and the Ge content is x, then the Si content is (1−x), where 0<x<1. If the first type doped crystalline Ge-containing layer uses the material of the first type doped crystalline GeSn layer and the Ge content is x, then the Sn content is (1−x), wherein 0<x<1. Taking the first type doped crystalline SiGe layer as an example, FIG. 2 illustrates a relationship between the Ge content in the first type doped crystalline SiGe layer and conduction bad energy (Ec)/valence band energy (Ev) of the first type doped crystalline SiGe layer. As shown in FIG. 2, in the first type doped crystalline SiGe layer, the Ec and Ev increase with the increase of the Ge content, while the band gap between Ec and By decreases with the increase of the Ge content. When the photovoltaic cell 10 is illuminated to generate electron-hole pairs, the electrons and holes may diffuse or drift to the electrodes 108, 110, respectively, allowing them to be carried out. Therefore, the Ec of the first type doped crystalline SiGe layer must be greater than the Ec of the first type doped mono-crystalline silicon substrate 100, otherwise an incorrect electric field direction would prevent the electrons from being successfully carried out. As such, in one preferred embodiment, for example, the first type doping concentration of the first type doped crystalline SiGe layer varies gradiently such that the Ev of the first type doped crystalline SiGe layer increases gradually to allow the electrons to be successfully carried out. In the present embodiment, the first type doping concentration decreases gradually from the electrode 110 toward the first type doped mono-crystalline silicon substrate 100 to allow the electrons to be successfully carried out. In another embodiment, however, the first type doping concentration of the first type doped crystalline Ge-containing layer 106 does not vary gradiently.

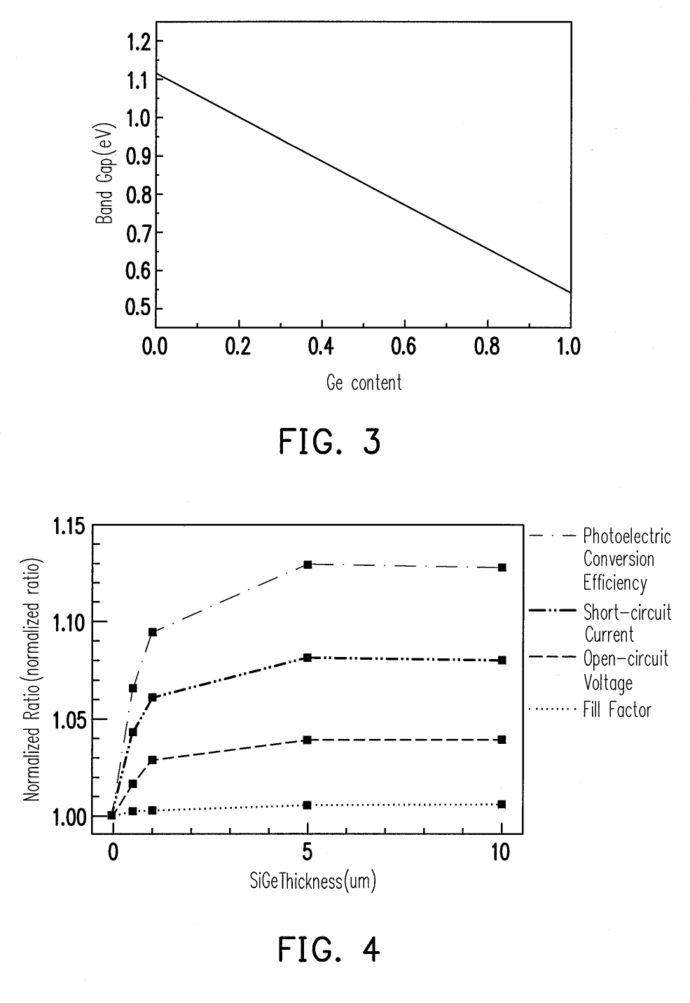

Taking the first type doped crystalline SiGe layer as an example, FIG. 3 illustrates a relationship between the Ge content in the first type doped crystalline SiGe layer and the band gap of the first type doped crystalline SiGe layer. As can be clearly seen from FIG. 3, the band gap of the first type doped crystalline SiGe layer decreases with the increase of the Ge content. That is, as the Ge content becomes higher in the first type doped crystalline SiGe layer, the band gap of the first type doped crystalline SiGe layer becomes lower and, therefore, the first type doped crystalline SiGe layer is enabled to absorb a broader spectrum of solar light.

FIG. 4 illustrates a relationship between the thickness (micro-meters, μm) of the first type doped crystalline Ge-containing layer and the photoelectric conversion efficiency/open-circuit voltage/short-circuit current/fill factor of the photovoltaic cell. The first type doped crystalline Ge-containing layer is exemplarily implemented as the first type doped crystalline SiGe layer. In another embodiment, the first type doped crystalline GeSn layer or another suitable material can also be used. As can seen from FIG. 4, the photoelectric conversion efficiency, open-circuit voltage, short-circuit current and fill factor increase with the increase of the thickness of the first type doped crystalline SiGe layer.

Taking the photovoltaic cell 10 as an example, the method of fabricating the photovoltaic cell of the present invention is explained below.

### First Method

A first type doped mono-crystalline silicon substrate 100 is first provided. An intrinsic amorphous silicon layer 102, a second type doped amorphous silicon layer 104 and an electrode 108 are sequentially formed on a front surface 100a of the first type doped mono-crystalline silicon substrate 100. A first type doped crystalline Ge-containing layer 106 and an electrode 110 are then sequentially formed on a rear surface 100b of the first type doped mono-crystalline silicon substrate 100.

### Second Method

A first type doped mono-crystalline silicon substrate 100 is first provided. An intrinsic amorphous silicon layer 102 and a second type doped amorphous silicon layer 104 are sequentially formed on a front surface 100a of the first type doped mono-crystalline silicon substrate 100. A first type doped crystalline Ge-containing layer 106 is then formed on a rear surface 100b of the first type doped mono-crystalline silicon substrate 100. An electrode 108 and an electrode 110 are formed on the second type doped amorphous silicon layer 104 and the first type doped crystalline Ge-containing layer 106, respectively.

### Third Method

A first type doped mono-crystalline silicon substrate 100 is first provided. A first type doped crystalline Ge-containing layer 106 and an electrode 110 are sequentially formed on a rear surface 100b of the first type doped mono-crystalline silicon substrate 100. An intrinsic amorphous silicon layer 102, a second type doped amorphous silicon layer 104 and an electrode 108 are then sequentially formed on a front surface 100a of the first type doped mono-crystalline silicon substrate 100.

### Fourth Method

A first type doped mono-crystalline silicon substrate 100 is first provided. A first type doped crystalline Ge-containing layer 106 is formed on a rear surface 100b of the first type doped mono-crystalline silicon substrate 100. An intrinsic amorphous silicon layer 102 and a second type doped amorphous silicon layer 104 are then sequentially formed on a front surface 100a of the first type doped mono-crystalline silicon substrate 100. An electrode 108 and an electrode 110 are then formed on the second type doped amorphous silicon layer 104 and the first type doped crystalline Ge-containing layer 106, respectively.

Because the above methods only require to form a high quality amorphous silicon layer on the front surface 100a of the first type doped mono-crystalline silicon substrate 100, this can reduce difficulty in fabrication and hence the fabrication cost. In addition, it is noted that the first type doping and the second type doping involved in the structure and fabrication methods of the above embodiments are of opposite types. That is, if the first type doping is p type doping, then the second type doping is n type doping. On the contrary, if the first type doping is n type doping, then the second type doping is p type doping. Furthermore, the material of the first type doped crystalline Ge-containing layer in the structure and fabrication method of the above embodiments include the first type doped crystalline SiGe layer, first type doped crystalline GeSn layer or another suitable material.

The foregoing description of the preferred embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. The abstract of the disclosure is provided to comply with the rules requiring an abstract, which will allow a searcher to quickly ascertain the subject matter of the technical disclosure of any patent issued from this disclosure. It is submitted with the understanding that it will not be used to interpret or limit the scope or meaning of the claims. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A photovoltaic cell comprising:
a first type doped mono-crystalline silicon substrate having a front surface and a rear surface;
an intrinsic amorphous silicon layer disposed on the front surface;
a second type doped amorphous silicon layer disposed on the intrinsic amorphous silicon layer;
a first type doped crystalline Ge-containing layer disposed on the rear surface; and
a pair of electrodes electrically connected to the second type doped amorphous silicon layer and the first type doped crystalline Ge-containing layer.

2. The photovoltaic cell according to claim 1, wherein the first type doped mono-crystalline substrate has a crystalline orientation of (100), (110), or (111).

3. The photovoltaic cell according to claim 1, wherein the first type doped mono-crystalline silicon substrate is a p type doped mono-crystalline silicon substrate, and the second type doped amorphous silicon layer is an n type doped amorphous silicon layer.

4. The photovoltaic cell according to claim 1, wherein a band gap of the second type doped amorphous silicon layer is substantially less than that of the intrinsic amorphous silicon layer, the band gap of the intrinsic amorphous silicon layer is substantially greater than that of the first type doped mono-crystalline silicon substrate, and the band gap of the first type doped mono-crystalline silicon substrate is substantially greater than that of the first type doped crystalline Ge-containing layer.

5. The photovoltaic cell according to claim 1, wherein the band gap of the second type doped amorphous silicon layer ranges between about 1.5 eV and about 2.0 eV, the band gap of the intrinsic amorphous silicon layer ranges between about 1.5 eV and about 2.0 eV, the band gap of the first type doped mono-crystalline silicon substrate ranges between about 1.0 eV and about 1.1 eV, and the band gap of the first type doped crystalline Ge-containing layer ranges between about 0.6 eV and about 1.1 eV.

6. The photovoltaic cell according to claim 1, wherein the thickness of the first type doped mono-crystalline silicon substrate ranges between about 50 um and about 500 um.

7. The photovoltaic cell according to claim 1, wherein the doping concentration of the first type doped mono-crystalline silicon substrate ranges between about 10¹⁵ cm⁻³ and about 10¹⁷ cm⁻³.

8. The photovoltaic cell according to claim 1, wherein a thickness of the second type amorphous silicon layer ranges between about 1 nm and about 20 nm.

9. The photovoltaic cell according to claim 1, wherein a doping concentration of the second type doped amorphous silicon layer ranges between about 10¹⁸ cm⁻³ and about 10²¹ cm⁻³.

10. The photovoltaic cell according to claim 1, wherein the first type doped crystalline Ge-containing layer is a first type doped crystalline SiGe layer or a first type doped crystalline GeSn layer.

11. The photovoltaic cell according to claim 1, wherein the Ge content in the first type doped crystalline SiGe layer is substantially higher than 10%, and the Si content in the first type doped crystalline SiGe layer is substantially lower than 90%.

12. The photovoltaic cell according to claim 1, wherein the thickness of the first type doped crystalline Ge-containing layer ranges between about 10 nm and about 10 um.

13. The photovoltaic cell according to claim 1, wherein the doping concentration of the first type doped crystalline Ge-containing layer ranges between about 10¹⁵ cm⁻³ and about 10²¹ cm⁻³.

14. The photovoltaic cell according to claim 1, wherein the pair of electrodes comprises:
a first electrode disposed on the second type doped amorphous silicon layer; and
a second electrode disposed on the first type doped crystalline Ge-containing layer, wherein the second electrode and the first type doped mono-crystalline silicon substrate are disposed on opposite sides of the first type doped crystalline Ge-containing layer, respectively.

15. The photovoltaic cell according to claim 14, wherein the first electrode is a transparent electrode and the second electrode is a reflective electrode.
